(19) United States
(12) Patent Application Publication
(10) Pub. No.: US 2001/0014533 A1
(43) Pub. Date: Aug. 16, 2001

(54) METHOD OF FABRICATING SALICIDE

(76) Inventor: SHIH-WEI SUN, TAIPEI (TW)

Correspondence Address: J. C. Patents, Inc., 1340 Reynolds Avenue, Suite 114, Irvine,, CA, 92614, US

(21) Appl. No.: 09/227,116

(22) Filed: Jan. 8, 1999

(51) Int. Cl. H01L 21/44

(52) U.S. Cl. 438/655

(57) ABSTRACT

A method fabricating salicide. A substrate having a conductive line is provided. An oxide layer is formed on the conductive line and the substrate. A spacer is formed on the oxide layer over a sidewall of the spacer. The oxide layer is etched to leave a recess surface between the spacer and the conductive line, so as to expose the substrate and a top surface of the conductive line. A metal layer is formed to cover the conductive line and extends on the recessed surface of the oxide layer. The metal layer is converted into a metal silicide layer.

### BACKGROUND OF THE INVENTION

1. Field of the Invention

The invention relates in general to a method of fabricating a self-aligned silicide (salicide), and more particularly, to a method of fabricating a salicide layer on the conductive regions of a semiconductor device.

2. Description of the Related Art

Due to the higher and higher device integration of semiconductors, the linewidth and patterns of devices are formed smaller and smaller. The shrinkage of the linewidth causes the resistance of a polysilicon gate (poly-gate) of a metal-oxide semiconductor (MOS) and the conductive wires of a device or a circuit increases greatly. To adjust the resistance, methods such as the formation of a salicide has been widely applied in VLSI or ULSI circuit. In the conventional method of forming a salicide layer, a metal layer is formed on a silicon surface. By performing a thermal process, the metal layer reacts with the silicon to form a silicide layer. The metal silicide has a better conductivity than silicon. Therefore, an improved electric operation is obtained for the poly-gate and the conductive wires formed by the conductive layer comprising silicon and metal suicide.

FIG. 1A and FIG. 1B are cross sectional views showing a conventional method for fabricating a salicide layer on a silicon or polysilicon surface to reduce the device resistance.

In FIG. 1A, a substrate 10 having a MOS device is provided. The MOS device comprises a source/drain region 19 in the substrate, and a gate 12 on the substrate 10. The gate 12 and the substrate 10 are isolated with each other by a gate oxide layer 11. The gate 12 further comprises a side wall covered by a spacer 16. A metal layer 20 is formed on the MOS device.

In FIG. 1B, using rapid thermal process, the metal layer 20 reacts with the silicon of the poly-gate 12 and the source/drain region 19 to form a metal silicide layer 22 on both the poly-gate 12 and the source/drain region 19. The metal layer 20 which did not react with silicon completely is then removed by wet etching.

In the conventional method mentioned above, a spacer 16 is typically formed to between the gate 12 and the drain region 19. As the integration increases and consequently decreases the linewidth, the spacer 16 is formed with a further thinner thickness. Therefore, a coupling capacitance (fringe capacitance) is caused between the gate 12 and the source/drain region 19. The coupling capacitance becomes more obvious as the conductivity of the gate 19 is enhanced by the formation of the salicide layer 22. Moreover, while an oxide spacer is in used, a lateral formation of the metal silicide layer 22 occurs rapidly.

To obtain a higher conductivity, or to reduce the resistivity of the metal silicide layer, as well as of the gate and source/drain region, a C54 lattice structure of the metal silicide layer is favored. Therefore, a phase transition between C49 to C54 is required. As the linewidth becomes narrower and narrower, the required temperature for the phase transition becomes higher and higher. However, it is known that as the linewidth decreases, the metal silicide layer tends to agglomerate in a lower temperature. The conventional method thus meets a bottle neck for further development in reducing linewidth and resistance.

### SUMMARY OF THE INVENTION

It is an object of the invention to provide a method of fabricating a salicide layer with an increased surface area. Consequently, the conductivity is increased.

It is another object of the invention to provide a method of fabricating a salicide layer. The method allows the spacer to be formed with a thinner thickness without causing a fringe capacitance.

To achieve the above-mentioned objects and advantages, a method of fabricating a salicide layer. A substrate having a conductive line is provided. An oxide layer is formed on the substrate and the conductive line. The oxide layer further comprises a thermally grown oxide layer and a deposited liner oxide layer on the thermally grown oxide layer. A spacer is formed on the oxide layer which covers a side wall of the conductive line. The oxide layer etched to result in a lower surface level between the conductive line and the spacer. Therefore, the gate does not have a top surface exposed, but also has a top end of the side wall exposed. A metal layer is formed on the substrate, the remaining oxide layer, and the spacer. A thermal process is performed to cause a reaction between the conductive line and the metal layer, so that a metal silicide layer is formed to cover the top surface and the top end of the side wall of the conductive line. Even the linewidth of the fabrication process is shrunk, the metal silicide layer is formed with an increased surface area and thickness. A better conductivity can thus be obtained.

The exposed part of the side wall is controlled can be specifically required. For example, the etching process of the oxide layer can be extended to expose a larger part of the side wall, or even the whole side wall. A recess with a large step height, that is, a high aspect ratio is formed between the conductive line and the spacer by the extended etching. By performing the similar process as above, an air gap is formed between the metal silicide layer and the remaining oxide layer, or the substrate while the whole side wall of the conductive line is exposed. As a consequence, the fringe capacitance between the metal silicide layer, or the conductive line and the substrate, or a conductive region in the substrate is suppressed, or even eliminated.

Both the foregoing general description and the following detailed description are exemplary and explanatory only and are not restrictive of the invention, as claimed.

### BRIEF DESCRIPTION OF THE DRAWINGS

FIG. 1A and FIG. 1B are cross sectional views showing a conventional method for fabricating a salicide layer;

FIG. 2A to FIG. 2F are cross sectional views showing a method of fabricating a salicide layer in a preferred embodiment according to the invention; and

FIG. 3A to FIG. 3C shows another embodiment of the fabricating a salicide layer according to the invention.

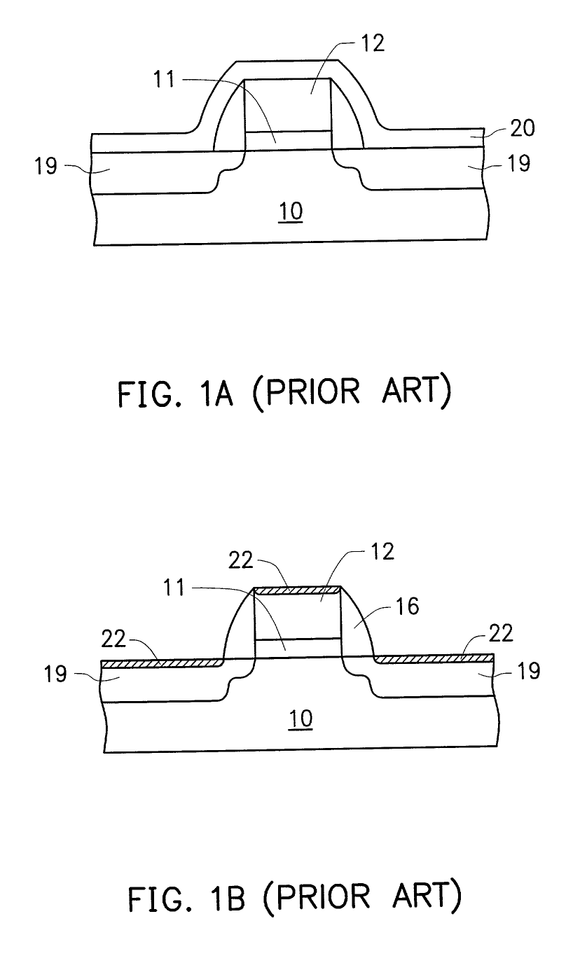

### DESCRIPTION OF THE PREFERRED EMBODIMENTS

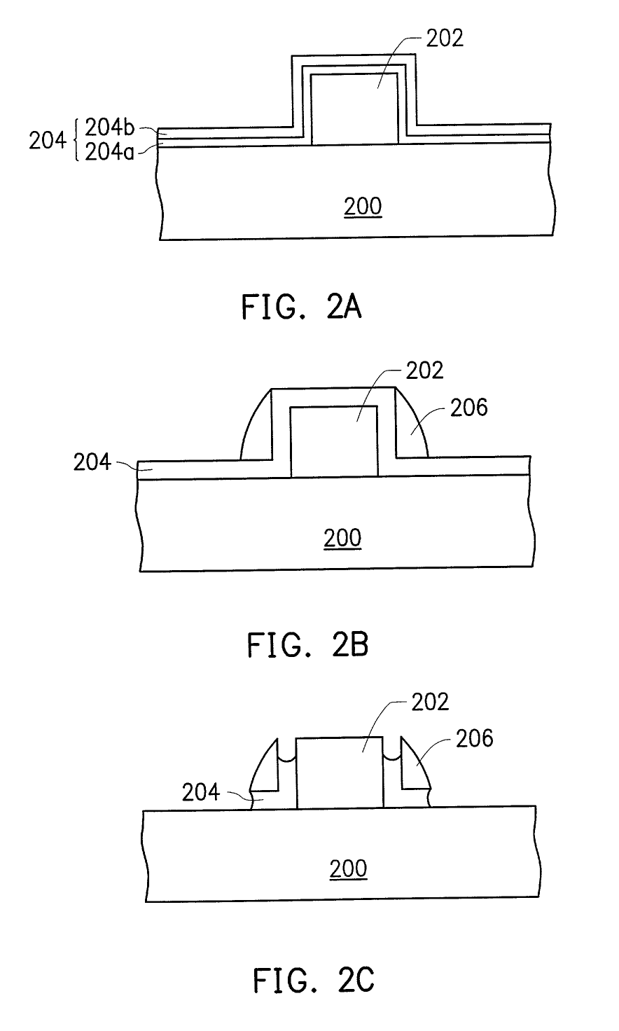

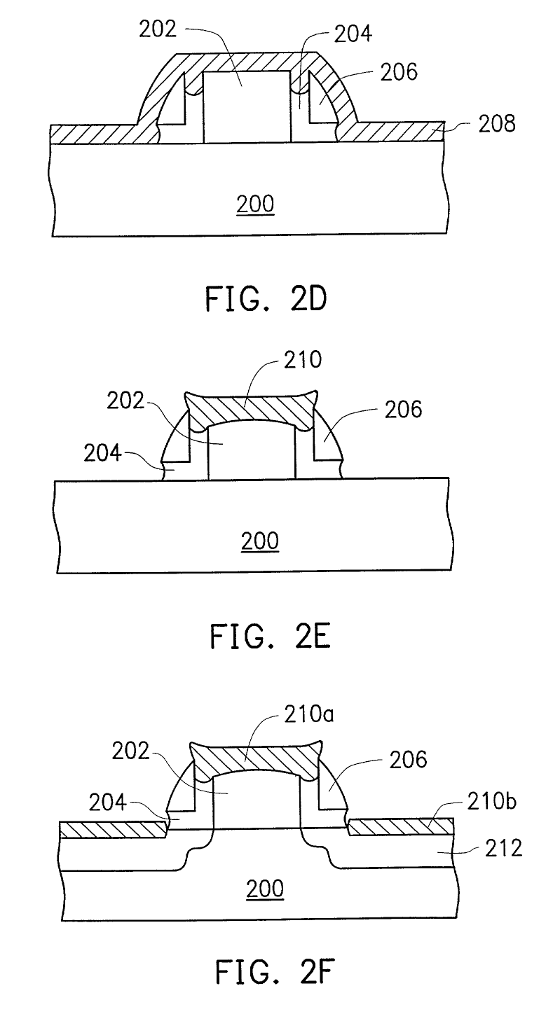

FIG. 2A to FIG. 2F are cross sectional views showing a preferred embodiment according to the invention, in which a salicide layer is formed with an increased surface area. As shown in FIG. 2A, a substrate 200 comprising a conductive line 202 is provided. The conductive line 200 may comprise a polysilicon layer, a single crystalline or and epitaxy silicon layer, or an amorphous silicon layer. An oxide layer 204 is formed on the conductive line 202 and the substrate 200. The oxide layer 204 further comprises a thermally grown oxide layer 204a, and a deposited oxide layer 204b on the thermally grown oxide layer 204a. Typically, the thermally grown oxide 204a has a thickness as thin as about 30 to 300 Å to avoid side effects such as lift over of the conductive line at bottom edge, while the deposited oxide layer 204b is formed with a thickness ranged between, for example, 50 to 1000 Å. It is appreciated that the total thickness of the oxide layer 204 can be adjusted and controlled as specifically requirements, even a range beyond thickness of the typical values mentioned here.

In FIG. 2B, a spacer 206 is formed on a part of the oxide layer 204. The part of the oxide layer 204 covered by the spacer 206 covers a side wall of the conductive line 202. Preferably, the spacer 206 comprises nitride with a thickness between 200 to 300 nm. Again, it is appreciated that the actual thickness of the spacer 206 has to be determined by the specific requirement for practical application without being limited to this range.

In FIG. 2C, the oxide layer 204 is etched to expose the substrate 200 and a top surface of the conductive line 202. A surface level of the oxide layer 204 lower than the top surface of the conductive line 202 is resulted between the spacer 206 and the conductive line 202. That is, after being etched, a recess is formed between the conductive line 202 and the spacer 206. The dimension of the recess can be adjusted by controlling the etching condition such as etching time, components of etchant or other parameters.

In FIG. 2D, a metal layer 208, for example, a titanium (Ti) layer, a cobalt (Co) layer, a platinum (Pt) layer, a nickel (Ni) layer, a palladium (Pd) layer, or other refractory metal layers, is formed on the oxide layer 204, the spacer 206, the conductive line 202, and fills the recess between the spacer 206 and the conductive line 202.

In FIG. 2E, a thermal process is performed to cause a silicide reaction. The metal layer 28 is thus reacted with the conductive line 202 to form a metal silicide layer 210, for example, a titanium silicide (TiSi₂) layer, a cobalt silicide (CoSi₂) layer, a platinum silicide (PtSi) layer, a palladium silicide (PdSi₂) layer, or a nickel silicide (NiSi₂) layer, on the conductive line 202. The remaining unreacted metal layer is then removed, for example, by wet etching. As shown in the figure, the metal silicide layer 210 has a wider edge part and a narrower middle part. However, the overall thickness of the metal silicide layer 210 is thicker than the thickness of a metal silicide layer formed by the conventional fabrication process. The edge part extends between the spacer 206 and the conductive line 202 to fill the recess formed by etching the oxide layer 204 shown in FIG. 2C.

FIG. 2F shows the application of the above embodiment shown in FIGS. 2A to 2E to a device such as a metal-insulation semiconductor (MIS) or a metal-oxide semiconductor (MOS). After the formation of the spacer 206 on a side wall of a gate 202 and the etching step of the oxide layer 204 as shown in FIG. 2C, a conductive region, that is, a source/drain region 212 in this example is formed in the substrate 200. Again, a metal layer is formed on the substrate 200, the spacer 206, the gate 202, the source/drain region 212 and fills the recess between the spacer 206 and the gate 202. A thermal process is performed to cause a silicide reaction between the metal layer and the gate 202 and the source/drain region 212. Metal silicide layers 210a and 210b are formed on the top surface of the gate 202 and the source/drain region 212. The metal layer does not only cover the top surface of the gate 202, but also the upper part of the sidewall of the gate 202. The reacting surface area for silicide reaction is larger than that of the conventional process. The metal silicide 210a is thus formed thicker than the metal silicide layer 210b.

Apart from the drawbacks mentioned in the paragraphs of the related prior art, the conventional salicide process further exhibits a limitation related to the fact that the gate and the source/drain suicides are formed at the same time. On the gate, it is desirable for the silicide to have the lowest possible sheet resistance, so that the gate electrode also possesses a low interconnect resistance. To achieve this, a thick silicide layer is needed. Over the source/drain region, however, the silicide can be only of limited thickness, in order to prevent excess consumption of the substrate silicon by silicide formation. Thus, a thicker silicide, though favorable at the gate level, is detrimental to contact (on the source/drain) formation, and vice versa. From the conventional one-step fabrication process, the silicide over both the gate and the soruce/drain region is formed with a same thickness. Therefore, a trade off between the silicide thickness over the gate and the source/drain region has to be made. The optimum condition to the performance of the device can not be obtained. Or alternatively, a two-step process in which silicide is formed on the gate first, and on the contact region (source/drain region) at a later stage with a different thickness. However, the two-process is so complex that a misalignment is caused easily. In addition, it is not economic in consideration of time and fabrication cost. In the invention, the silicide over both gate and the source/drain region is formed at the same time, but with different thickness. Therefore, the above problem is solved without additional fabrication process or cost.

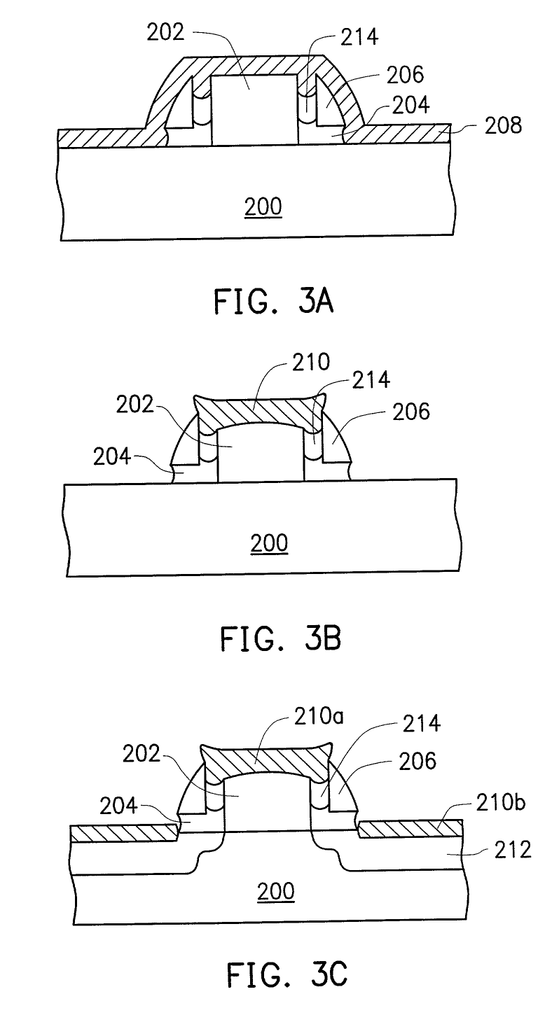

In another aspect of the invention, to solve the problem related to fringe capacitance, the invention further provides another method for fabricating a salicide. The fabricating process is shown as FIG. 3A to FIG. 3C in view of FIG. 2A to FIG. 2C. The following method is actually a modification of the method shown in FIG. 2A to FIG. 2F.

As shown from FIG. 2A to FIG. 2F, an oxide layer 204 comprising a thermally grown oxide layer 204a and a deposited oxide layer 204b is formed on a substrate 200 and a conductive line 202 on the substrate 200. A spacer 206, for example, a nitride spacer, is formed on a part of the oxide layer 204. The part of the oxide layer 204 covered by the spacer 206 covers a side wall of the conductive line 202. The oxide layer 204 is etched, so that a recess is resulted between the conductive line 202 and the spacer 206. The recess can be formed with a depth deep enough to result in a large step height, or even as deep as the length of the sidewall, so as to cause a deposition layer formed subsequently failing to fill the recess and leave an air gap.

In FIG. 3A, a metal layer 208 is formed to cover the top surface of the conductive line 202, the substrate 200, the spacer 206, and a part of the recess. Due to the large step height, the metal layer 208 can not fill the recess completely. Therefore, an air gap 214 is formed under the metal layer 208 and over the oxide layer 204 between the conductive line 202 and the spacer 206.

In FIG. 3B, a thermal process is performed to cause a silicide reaction between the metal layer 208 and the conductive line 202. A metal silicide layer 210 is thus formed on the top surface of the conductive line 202 and covers the air gap 214. Similar to the previous embodiment, the conductive line 202 covered by the metal layer 208 does not only includes the top surface, but also a part of the side wall of the conductive line 202. Therefore, the metal silicde layer 210 is formed with a wider edge part and a narrower middle part. However, the overall thickness is thicker than that of a metal silicide layer formed by a conventional method.

FIG. 3C shows the application of the above embodiment shown in FIGS. 3A and 3B to a device such as a metal-insulation semiconductor (MIS) or a metal-oxide semiconductor (MOS). After the formation of the spacer 206 on a gate 202 and the etching step of the oxide layer 204 as shown in FIG. 2C, a conductive region, that is, a source/drain region 212 in this example is formed in the substrate 200. Different from the device shown in FIG. 2F, the oxide layer 204 is removed to leave a deep recess which cannot be filled completely by a deposition layer formed subsequently. An air gap 214 is thus formed. Again, a metal layer is formed on the substrate 200, the spacer 206, and the source/drain region 212 and partly fills the recess between the spacer 206 and the gate 202. A thermal process is performed to cause a silicide reaction between the metal layer and the gate 202 and the source/drain region 212. Metal silicide layers 210a and 210b are formed on the top surface of the gate 202 and the source/drain region 212. An air gap 214 remains under the metal silicide layer 210a and over the oxide layer 204 between the gate 202 and the spacer 206. The metal layer does not only cover the top surface of the gate 202, but also the upper part of the sidewall of the gate 202. The reacting surface area is larger than that of the conventional process. The metal silicide 210a is thus formed thicker than the metal silicide layer 210b.

The larger surface area of the metal silicide layer reduces the resistivity thereof. This embodiment also allows the metal silicide layer 210a on the gate 202 to be formed thicker than the metal silicide layer 30b on the source/drain region 212 by the same step. Moreover, the formation of the air gap 214 suppresses, or eliminates the induction of the fringe capacitance between the conductive line (gate) 202 and the conductive region (source/drain region) 212.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A method of fabricating a salicide layer, comprising:
providing a substrate having a conductive line thereon;
forming an oxide layer on the substrate and the conductive line;
forming a spacer on the oxide layer over a side wall of the conductive line;
removing a part of the oxide layer to expose the substrate, a top surface and an upper part of the side wall of the conductive line, so that a recess is formed between the spacer and the side wall of the conductive line;
forming a metal layer on the conductive line, the substrate and to fill the recess; and
converting the metal layer into a silicide layer.

2. The method according to claim 1, wherein the conductive line comprises a silicon layer made of polysilicon, single crystalline, epitaxy silicon, or amorphous silicon.

3. The method according to claim 1, wherein the oxide layer comprises a thermally grown oxide layer and a deposited oxide layer.

4. The method according to claim 3, wherein the thermally grown oxide layer has a thickness of about 30 to 300 Å.

5. The method according to claim 3, wherein the deposited oxide layer has a thickness of about 50 to 1000 Å.

6. The method according to claim 1, wherein the metal layer comprises a refractory metal layer selected from a group consisting of titanium, cobalt, palladium, platinum, and nickel.

7. The method according to claim 1, wherein the step of converting the metal layer into a silicide layer comprises further the steps of:
performing a thermal process to the metal layer to cause a silicide reaction between the metal and the underlying conductive line; and
removing any unreacted metal layer.

8. A method of fabricating a salicide layer, comprising:
providing a substrate having a gate thereon;
forming an oxide layer on the substrate and the gate;
forming a spacer on the oxide layer over a side wall of the gate;
removing a part of the oxide layer to expose the substrate and a part of the gate, the part of the exposed gate comprising a top surface and an upper part of the side wall;
forming a source/drain region in the substrate with the gate as a mask;
forming a metal layer to cover the exposed part of the gate and the source/drain region; and
converting the metal layer into a silicide layer.

9. The method according to claim 8, wherein the oxide layer comprises a thermally grown oxide layer and a deposited oxide layer.

10. The method according to claim 9, wherein the thermally grown oxide layer has a thickness of about 30 to 300 Å.

11. The method according to claim 9, wherein the deposited oxide layer has a thickness of about 50 to 1000 Å.

12. The method according to claim 8, wherein the metal layer comprises a refractory metal layer selected from a group consisting of titanium, cobalt, palladium, platinum, and nickel.

13. The method according to claim 8, wherein the step of converting the metal layer into a silicide layer comprises further the steps of:
performing a thermal process to the metal layer to cause a silicide reaction between the metal and the underlying conductive line; and
removing any unreacted metal layer.

14. The method according to claim 8, wherein the silicide layer covering the gate is thicker than the silicide layer covering the source/drain region.

15. A method of fabricating a salicide layer, comprising:
providing a substrate having a conductive line thereon;
forming an oxide layer on the substrate and the conductive line;
forming a spacer on the oxide layer over a side wall of the conductive line;
removing a part of the oxide layer to expose the substrate and a top surface and an upper part of the side wall of the conductive line;
forming a metal layer on the conductive line and the substrate, and to leave an air gap under the metal layer and over the remaining oxide layer between the side wall of the conductive line and the spacer; and
converting the metal layer into a silicide layer.

16. The method according to claim 15, wherein the oxide layer comprises a thermally grown oxide layer and a deposited oxide layer.

17. The method according to claim 16, wherein the thermally grown oxide layer has a thickness of about 30 to 300 Å.

18. The method according to claim 16, wherein the deposited oxide layer has a thickness of about 50 to 1000 Å.

19. The method according to claim 15, wherein the metal layer comprises a refractory metal layer selected from a group consisting of titanium, cobalt, palladium, platinum, and nickel.

20. The method according to claim 15, wherein the step of converting the metal layer into a silicide layer comprises further the steps of:
performing a thermal process to the metal layer to cause a silicide reaction between the metal and the underlying conductive line; and
removing any unreacted metal layer.

21. A method of fabricating a salicide layer, comprising:
providing a substrate having a gate thereon;
forming an oxide layer on the substrate and the gate;
forming a spacer on the oxide layer over a side wall of the gate;
removing a part of the oxide layer to expose the substrate and a part of the gate, the part of the exposed gate comprising a top surface and an upper part of the side wall;
forming a source/drain region in the substrate with the gate as a mask;
forming a metal layer to cover the exposed part of the gate and the source/drain region, so that an air gap is formed under the metal layer and over the remaining oxide layer between the side wall of the gate and the spacer; and
converting the metal layer into a silicide layer.

22. The method according to claim 21, wherein the oxide layer comprises a thermally grown oxide layer and a deposited oxide layer.

23. The method according to claim 22, wherein the thermally grown oxide layer has a thickness of about 30 to 300 Å.

24. The method according to claim 22, wherein the deposited oxide layer has a thickness of about 50 to 1000 Å.

25. The method according to claim 20, wherein the metal layer comprises a refractory metal layer selected from a group consisting of titanium, cobalt, palladium, platinum, and nickel.

26. The method according to claim 21, wherein the step of converting the metal layer into a silicide layer comprises further the steps of:
performing a thermal process to the metal layer to cause a silicide reaction between the metal and the exposed conductive line; and
removing any unreacted metal layer.

27. The method according to claim 21, wherein the silicide layer covering the gate is thicker than the silicide layer covering the source/drain region.
